(19) United States
(12) Patent Application Publication
(10) Pub. No.: US 2022/0310168 A1
(43) Pub. Date: Sep. 29, 2022

(54) OPERATING METHOD OF STORAGE CONTROLLER USING COUNT VALUE OF DIRECT MEMORY ACCESS, STORAGE DEVICE INCLUDING STORAGE CONTROLLER, AND OPERATING METHOD OF STORAGE DEVICE

(71) Applicant: SAMSUNG ELECTRONICS CO., LTD., Suwon-si (KR)

(72) Inventors: Woohyun KANG, Hwaseong-si (KR); Hyuna KIM, Suwon-si (KR); Minkyu KIM, Suwon-si (KR); Donghyub KANG, Seoul (KR)

(21) Appl. No.: 17/511,738

(22) Filed: Oct. 27, 2021

(30) Foreign Application Priority Data
Mar. 24, 2021 (KR) 10-2021-0038222

(51) Int. Cl. G11C 16/10; G11C 16/26; G11C 16/30; G11C 16/32; G11C 29/42; G06N 20/00

(52) U.S. Cl. CPC G11C 16/102; G11C 16/26; G11C 16/30; G11C 16/32; G11C 29/42; G06N 20/00

(57) ABSTRACT

A method of operating a storage controller that communicates with a non-volatile memory device includes performing a first direct memory access (DMA) read operation on data stored in the non-volatile memory device, based on a first read voltage; updating a page count value of a DMA register, based on the first DMA read operation; determining whether data read by the first DMA read operation include an uncorrectable error; when it is determined that the data read by the first DMA read operation include the uncorrectable error, determining a second read voltage different from the first read voltage, based on the updated page count value of the DMA register, without an additional read operation on the data stored in the non-volatile memory device; and performing a second DMA read operation on the data stored in the non-volatile memory device, based on the second read voltage.

### CROSS-REFERENCE TO RELATED APPLICATION

This application claims priority under 35 U.S.C. § 119 to Korean Patent Application No. 10-2021-0038222, filed on Mar. 24, 2021, in the Korean Intellectual Property Office, the disclosure of which is incorporated by reference herein in its entirety.

### BACKGROUND

### 1. Field

Embodiments relate to an operating method of a storage controller using a count value of direct memory access, a storage device including the storage controller, and an operating method of storage device.

### 2. Description of the Related Art

A memory device stores data in response to a write request and outputs data stored therein in response to a read request. The memory device may be classified as a volatile memory device, which loses data stored therein when a power supply is interrupted, such as a dynamic random access memory (DRAM) device, a static RAM (SRAM) device, or a non-volatile memory device, which retains data stored therein even when a power supply is interrupted, such as a flash memory device, a phase-change RAM (PRAM), a magnetic RAM (MRAM), or a resistive RAM (RRAM).

According to the prior art, U.S. Pat. No. 10,490,285, an additional input/output (I/O) operation is required to obtain a logical count of “1” or “0” indicating a characteristic of a memory cell, and an additional operation that allows a memory controller to sense a logical count change is required. According to the prior art, U.S. Pat. No. 9,036,412, a plurality of sensing operations are required to obtain distribution information, and logical complexity such as an XOR operation increases. According to the prior art, U.S. Pat. No. 10,108,370, an additional sensing and logical operation is required to obtain count information between two read voltages. That is, according to the prior arts, an additional read operation is required to obtain characteristic information of a memory cell (e.g., a threshold voltage distribution), thereby causing a decrease of a speed of a memory device. There is required a method for obtaining characteristic information of a memory cell without a separate additional read operation.

### SUMMARY

According to an embodiment, a method of operating a storage controller that communicates with a non-volatile memory device includes: performing a first direct memory access (DMA) read operation on data stored in the non-volatile memory device, based on a first read voltage; updating a page count value of a DMA register, based on the first DMA read operation; determining whether data read by the first DMA read operation include an uncorrectable error; when it is determined that the data read by the first DMA read operation include the uncorrectable error, determining a second read voltage different from the first read voltage, based on the updated page count value of the DMA register, without an additional read operation on the data stored in the non-volatile memory device; and performing a second DMA read operation on the data stored in the non-volatile memory device, based on the second read voltage.

According to an embodiment, a method of operating a storage device that includes a non-volatile memory device, which stores data, and a storage controller, which controls the non-volatile memory device, includes: performing a first direct memory access (DMA) read operation on the data stored in the non-volatile memory device, based on a first read voltage; updating a page count value of a DMA register, based on the first DMA read operation; determining whether the data read by the first DMA read operation include an uncorrectable error; when it is determined that the data read by the first DMA read operation include the uncorrectable error, determining a second read voltage different from the first read voltage, based on the updated page count value of the DMA register, without an additional read operation on the data stored in the non-volatile memory device; and performing a second DMA read operation on the data stored in the non-volatile memory device, based on the second read voltage.

According to an embodiment, a storage device includes: a non-volatile memory device including a plurality of memory cells for storing data; and a storage controller, wherein the storage controller is configured to: perform a first direct memory access (DMA) read operation on data stored in the non-volatile memory device, based on a first read voltage; update a page count value of a DMA register; determine whether the data read by the first DMA read operation include an uncorrectable error; and when it is determined that the data read by the first DMA read operation include the uncorrectable error, determine a second read voltage different from the first read voltage based on the updated page count value of the DMA register, and perform a second DMA read operation on the data stored in the non-volatile memory device, based on the second read voltage.

### BRIEF DESCRIPTION OF THE FIGURES

Features will become apparent to those of skill in the art by describing in detail example embodiments with reference to the attached drawings in which:

FIG. 1 is a block diagram of a storage system according to an example embodiment.

FIG. 2 is a block diagram illustrating a storage controller of FIG. 1 in detail, according to an example embodiment.

FIG. 3 is a block diagram illustrating a non-volatile memory device of FIG. 1 in detail, according to an example embodiment.

FIG. 4 is a diagram illustrating a memory block included in a memory cell array of FIG. 3, according to an example embodiment.

FIG. 5A is a diagram illustrating threshold voltage distributions for multi-level cells, according to an example embodiment.

FIG. 5B is a diagram illustrating threshold voltage distributions for triple level cells, according to an example embodiment.

FIG. 5C is a diagram illustrating threshold voltage distributions for quadruple level cells, according to an example embodiment.

FIG. 6 is a diagram illustrating threshold voltage distributions of an initial time and a retention time, according to an example embodiment.

FIG. 7 is a diagram for describing a page count value according to an example embodiment.

FIG. 8 is a diagram illustrating a page count value and an optimized read voltage according to an example embodiment.

FIG. 9 is a table illustrating a relationship between page count values and optimized read voltages, according to an example embodiment.

FIG. 10A is a block diagram for describing read retry of a general storage device according to the prior art.

FIG. 10B is a diagram for describing an additional read operation for read retry of a general storage device according to the prior art.

FIG. 11 is a block diagram for describing read retry of a storage device according to an example embodiment.

FIG. 12 is a block diagram illustrating a machine learning device of FIG. 11, according to an example embodiment.

FIG. 13 is a diagram illustrating a machine learning model created by a model creator of FIG. 12, according to an example embodiment.

FIG. 14 is a flowchart illustrating an operating method of a storage device according to an example embodiment.

FIG. 15 is a flowchart illustrating an operating method of a general storage device according to the prior art.

FIG. 16 is a flowchart illustrating an operating method of a storage device according to an example embodiment.

FIG. 17 is a flowchart illustrating an operating method of a storage device according to an example embodiment.

FIG. 18 is a flowchart illustrating an operating method of a storage device according to an example embodiment.

FIG. 19 is a block diagram of a solid state drive system to which a storage device according to the present example embodiment is applied.

### DETAILED DESCRIPTION

Components described in the detailed description with reference to terms “part”, “unit”, “module”, “layer”, etc. and function blocks illustrated in drawings may be implemented in the form of software, hardware, or a combination thereof. The software may be a machine code, firmware, an embedded code, and application software. The hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

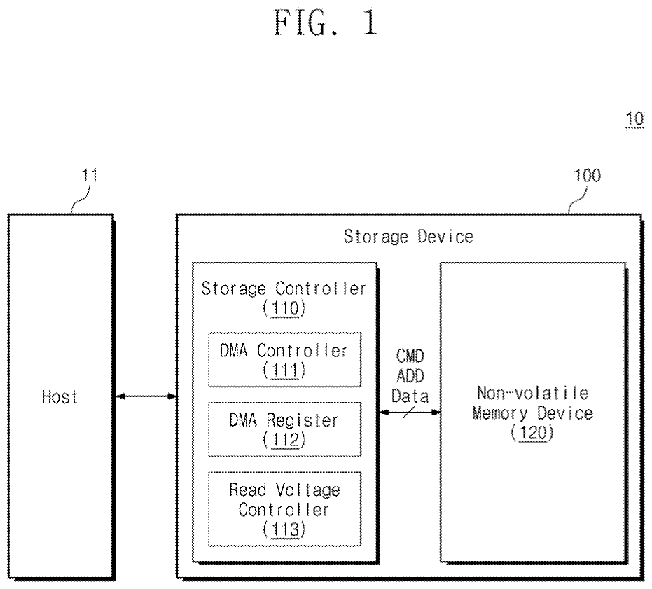

FIG. 1 is a block diagram of a storage system according to an example embodiment.

Referring to FIG. 1, a storage system 10 may include a host 11 and a storage device 100. In an example embodiment, the storage system 10 may be a computing system that is configured to process a variety of information, such as a personal computer (PC), a notebook, a laptop, a server, a workstation, a tablet PC, a smartphone, a digital camera, and a black box.

The host 11 may control overall operations of the storage system 10. The host 11 may store data in the storage device 100 or may read data stored in the storage device 100. In another implementation, the host 11 may allow the storage device 100 to perform a direct memory access (DMA) operation (e.g., a DMA write operation or a DMA read operation) with another external device (not illustrated).

The storage device 100 may include a storage controller 110 and a non-volatile memory device 120.

The storage controller 110 may store data in the non-volatile memory device 120 or may read data stored in the non-volatile memory device 120. The non-volatile memory device 120 may operate under control of the storage controller 110. For example, based on a command CMD indicating an operation and an address ADD indicating a location of data, the storage controller 110 may store the data in the non-volatile memory device 120 or may read the data stored in the non-volatile memory device 120.

The non-volatile memory device 120 may store data.

In an example embodiment, the non-volatile memory device 120 may be a NAND flash memory device, or one of various storage devices that retain data stored therein even though a power is turned off, such as a PRAM, an MRAM, a RRAM, and an FRAM.

The storage controller 110 may include a DMA controller 111, a DMA register 112, and a read voltage controller 113.

The DMA controller 111 may control a DMA operation between the non-volatile memory device 120 and another external device depending on a request of the host 11. The DMA controller 111 may process data according to the DMA operation in units of a page. The DMA controller 111 may update a page count value of the DMA register 112 based on a DMA read operation.

The DMA register 112 may store the page count value. In an example embodiment, the page count value may indicate a number of memory cells having a first bit value (e.g., bit value “1”) from among a plurality of memory cells, each of which has the first bit value or a second bit value (e.g., bit value “0”) and which belong to a page corresponding to the DMA read operation. The non-volatile memory device 120 may include a plurality of memory cells. The plurality of memory cells may form programmed threshold voltage distributions. In a logical page corresponding to the DMA read operation, a threshold voltage distribution corresponding to each of the plurality of memory cells may be classified as the first bit value or the second bit value, based on a read voltage and the DMA read operation. The DMA controller 111 may determine the number of memory cells indicating the first value from among a plurality of memory cells as the page count value. The DMA controller 111 may store the determined page count value in the DMA register 112.

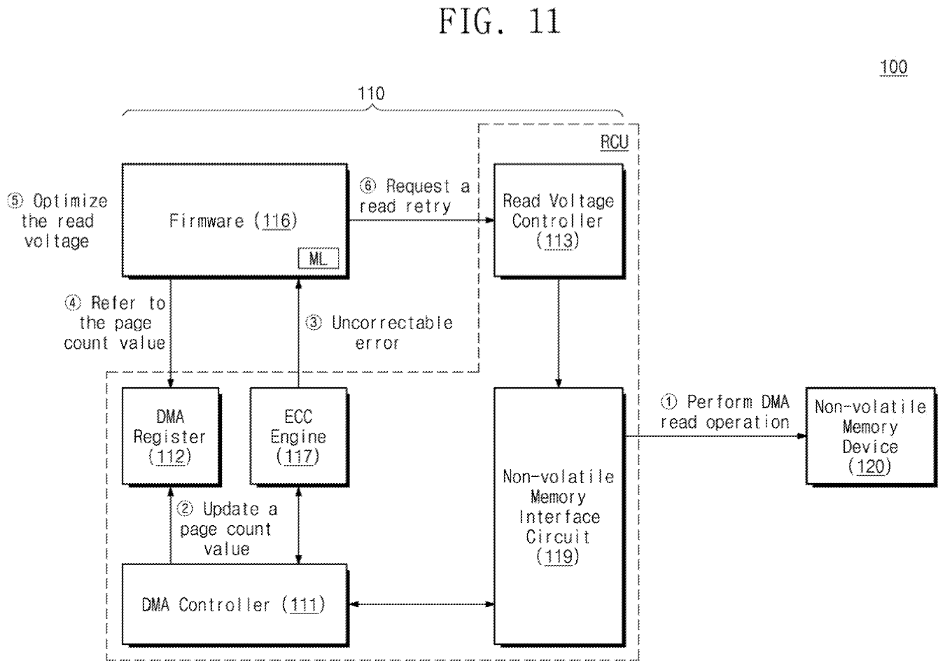

The read voltage controller 113 may control the read voltage of the non-volatile memory device 120. In an example embodiment, when it is determined that read retry is required (e.g., when an uncorrectable error occurs), the storage controller 110 may adjust the read voltage of the non-volatile memory device 120 through the read voltage controller 113, based on the page count value of the DMA register 112. The read retry may be performed when data obtained by a read operation are unavailable due to an uncorrectable error, and may include adjusting a read voltage and again performing the read operation. The read retry will be described in more detail with reference to FIGS. 11, 16, 17, and 18.

As described above, according to the present example embodiment, the storage controller 110 may adjust a read voltage based on a page count value obtained by the DMA read operation and perform the read retry.

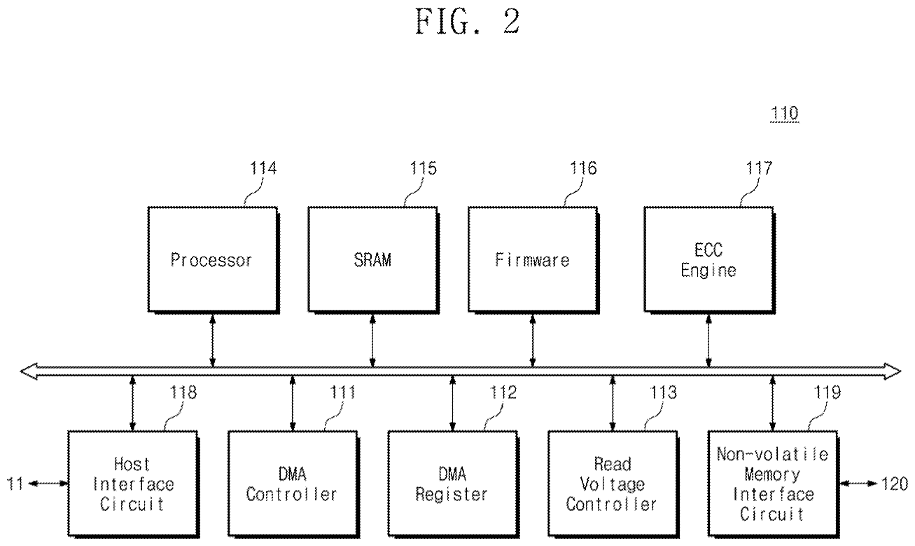

FIG. 2 is a block diagram illustrating a storage controller of FIG. 1 in detail, according to an example embodiment.

Referring to FIGS. 1 and 2, the storage controller 110 may communicate with the host 11 and the non-volatile memory device 120. The storage controller 110 may include the DMA controller 111, the DMA register 112, the read voltage controller 113, a processor 114, an SRAM 115, firmware 116, an ECC engine 117, a host interface circuit 118, and a non-volatile memory interface circuit 119.

The DMA controller 111, the DMA register 112, the read voltage controller 113, the processor 114, the SRAM 115, the firmware 116, the ECC engine 117, the host interface circuit 118, and the non-volatile memory interface circuit 119 may be interconnected through a bus. The DMA controller 111, the DMA register 112, and the read voltage controller 113 are similar to the DMA controller 111, the DMA register 112, and the read voltage controller 113 of FIG. 1, and thus, additional description will be omitted to avoid redundancy.

The processor 114 may control overall operations of the storage controller 110.

The SRAM 115 may be used as a buffer memory, a cache memory, or a working memory of the storage controller 110.

The firmware 116 may include a variety of information that is used for the storage controller 110 to operate. In an example embodiment, the firmware 116 may control a read retry operation of the storage controller 110. The firmware 116 may be stored in a memory, which stores instructions, such as a read only memory (ROM) and/or the non-volatile memory device 120 and may be executed by the processor 114.

The ECC engine 117 may detect and correct an error of data read from the non-volatile memory device 120. In an example embodiment, as the number of program and erase operations increases or as a time passing after data are stored in the non-volatile memory device 120 increases, an error level of the non-volatile memory device 120 may increase. The ECC engine 117 may have an error correction capacity of a given level. In the case where an error of data read from the non-volatile memory device 120 exceeds an error correction capacity of the ECC engine 117, the error of the data read from the non-volatile memory device 120 may not be corrected, in which case the ECC engine 117 may determine that data have an uncorrectable error. The firmware 116 may manage an uncorrectable error through the ECC engine 117. To reduce an error level of data that is read, the firmware 116 may perform read retry through the DMA controller 111 and the read voltage controller 113.

The host interface circuit 118 may be implemented based on at least one of various interfaces such as a SATA (Serial ATA) interface, a PCIe (Peripheral Component Interconnect Express) interface, a SAS (Serial Attached SCSI), an NVMe (Nonvolatile Memory express) interface, and an UFS (Universal Flash Storage) interface. The storage controller 110 may communicate with the host 11 through the host interface circuit 118. In an example embodiment, storage controller 110 may receive a signal requesting the DMA read operation from the host 11 through the host interface circuit 118.

The non-volatile memory interface circuit 119 may be implemented based on a NAND interface. The storage controller 110 may communicate with the non-volatile memory device 120 through the non-volatile memory interface circuit 119. In an example embodiment, under control of the DMA controller 111, the storage controller 110 may perform the DMA read operation on data stored in the non-volatile memory device 120 through the non-volatile memory interface circuit 119. In an example embodiment, under control of the read voltage controller 113, the storage controller 110 may adjust a read voltage, which is used for the DMA read operation at the non-volatile memory device 120, through the non-volatile memory interface circuit 119.

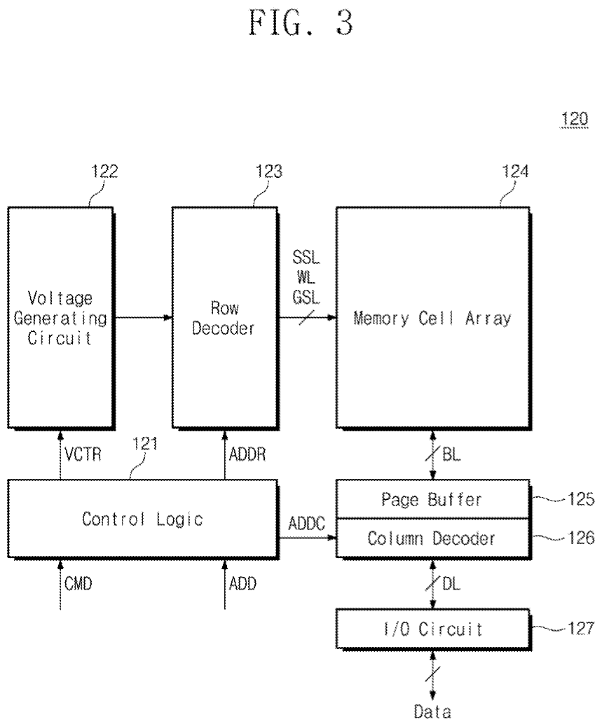

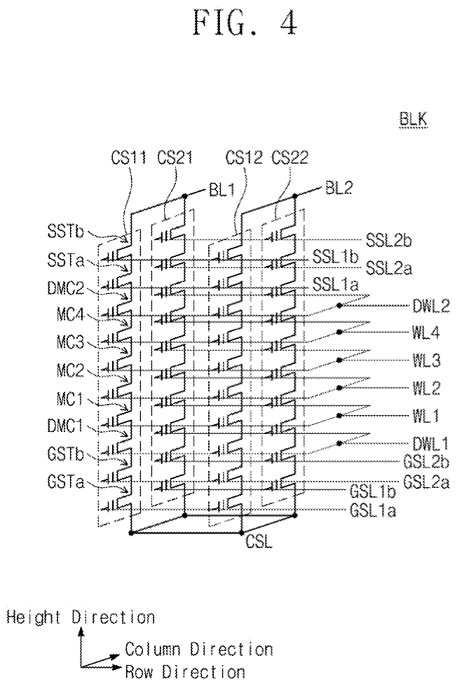

FIG. 3 is a block diagram illustrating a non-volatile memory device of FIG. 1 in detail, according to an example embodiment. FIG. 4 is a diagram illustrating a memory block included in a memory cell array of FIG. 3, according to an example embodiment.

Referring to FIGS. 1, 3, and 4, the non-volatile memory device 120 may communicate with the storage controller 110. The non-volatile memory device 120 may receive the address ADD and the command CMD from the storage controller 110. The non-volatile memory device 120 may exchange data with the storage controller 110.

The non-volatile memory device 120 may include control logic 121, a voltage generating circuit 122, a row decoder 123, a memory cell array 124, a page buffer 125, a column decoder 126, and an input/output (I/O) circuit 127.

The control logic 121 may receive the command CMD and the address ADD from the storage controller 110. The command CMD may be a signal directing an operation to be performed at the non-volatile memory device 120, such as a read operation, a write operation, or an erase operation. The address ADD may include a row address ADDR and a column address ADDC. The control logic 121 may generate the row address ADDR, the column address ADDC, and a read voltage control signal VCTR, based on the command CMD and the address ADD. The read voltage control signal VCTR may be a signal of controlling a read voltage that is generated by the voltage generating circuit 122.

In an example embodiment, the command CMD may include change request information of a read voltage for read retry. In another implementation, the control logic 121 may receive a signal of requesting a change of a read voltage, separately from the command CMD.

The voltage generating circuit 122 may control a voltage that is applied to the memory cell array 124 through the row decoder 123. In an example embodiment, the voltage generating circuit 122 may change a read voltage to be used in the DMA read operation, based on the read voltage control signal VCTR.

The row decoder 123 may receive the row address ADDR from the control logic 121.

The row decoder 123 may be connected with the memory cell array 124 through string selection lines SSL, word lines WL, and ground selection lines GSL. The row decoder 123 may decode the row address ADDR and may control voltages to be applied to the string selection lines SSL, the word lines WL, and the ground selection lines GSL based on a decoding result and a voltage received from the voltage generating circuit 122.

The memory cell array 124 may include a plurality of memory blocks. Each of the plurality of memory blocks may be similar in structure to a memory block BLK described in connection with FIG. 4. The memory block BLK illustrated in FIG. 4 may correspond to a physical erase unit of the non-volatile memory device 120. The physical erase unit may be changed to a page unit, a word line unit, a sub-block unit, etc.

Referring to FIG. 4, the memory block BLK may include a plurality of cell strings CS11, CS12, CS21, and CS22. The plurality of cell strings CS11, CS12, CS21, and CS22 may be arranged in a row direction and a column direction. For brevity of drawing, 4 cell strings CS11, CS12, CS21, and CS22 are illustrated in FIG. 4. The number of cell strings may increase or decrease in a row direction or a column direction.

Cell strings placed at the same column from among the plurality of cell strings CS11, CS12, CS21, and CS22 may be connected with the same bit line. The cell strings CS11 and CS21 may be connected with a first bit line BL1, and the cell strings CS12 and CS22 may be connected with a second bit line BL2.

Each of the plurality of cell strings CS11, CS12, CS21, and CS22 may include a plurality of cell transistors. The plurality of cell transistors may be implemented with a charge trap flash (CTF) memory cell. The plurality of cell transistors may be stacked in a height direction that is a direction perpendicular to a plane (e.g., a semiconductor substrate (not illustrated)) defined by the row direction and the column direction.

The plurality of cell transistors may be connected in series between the corresponding bit line (e.g., BL1 or BL2) and a common source line CSL. The plurality of cell transistors may include string selection transistors SSTa and SSTb, dummy memory cells DMC1 and DMC2, memory cells MC1 to MC4, and ground selection transistors GSTa and GSTb.

The serially-connected string selection transistors SSTa and SSTb may be provided between the serially-connected memory cells MC1 to MC4 and a corresponding bit line (e.g., BL1 and BL2). The serially-connected ground selection transistors GSTa and GSTb may be provided between the serially-connected memory cells MC1 to MC4 and the common source line CSL.

The second dummy memory cell DMC2 may be provided between the serially-connected string selection transistors SSTa and SSTb and the serially-connected memory cells MC1 to MC4, and the first dummy memory cell DMC1 may be provided between the serially-connected memory cells MC1 to MC4 and the serially-connected ground selection transistors GSTa and GSTb.

In the plurality of cell strings CS11, CS12, CS21, and CS22, memory cells placed at the same height from among the memory cells MC1 to MC4 may share the same word line. The first memory cells MC1 of the plurality of cell strings CS11, CS12, CS21, and CS22 may be placed at the same height from the substrate (not illustrated) and may share a first word line WL1. The second memory cells MC2 of the plurality of cell strings CS11, CS12, CS21, and CS22 may be placed at the same height from the substrate (not illustrated) and may share a second word line WL2. Likewise, the third memory cells MC3 of the plurality of cell strings CS11, CS12, CS21, and CS22 may be placed at the same height from the substrate (not illustrated) and may share a third word line WL3, and the fourth memory cells MC4 of the plurality of cell strings CS11, CS12, CS21, and CS22 may be placed at the same height from the substrate (not illustrated) and may share a fourth word line WL4.

Dummy memory cells placed at the same height from among the dummy memory cells DMC1 and DMC2 of the plurality of cell strings CS11, CS12, CS21, and CS22 may share the same dummy word line. The first dummy memory cells DMC1 of the plurality of cell strings CS11, CS12, CS21, and CS22 may share a first dummy word line DWL1, and the second dummy memory cells DMC2 of the plurality of cell strings CS11, CS12, CS21, and CS22 may share a second dummy word line DWL2.

String selection transistors placed at the same height and the same row from among the string selection transistors SSTa and SSTb of the plurality of cell strings CS11, CS12, CS21, and CS22 may share the same string selection line. The string selection transistors SSTb of the cell strings CS11 and CS12 may be connected with a string selection line SSL1b, and the string selection transistors SSTa of the cell strings CS11 and CS12 may be connected with a string selection line SSL1a. The string selection transistors SSTb of the cell strings CS21 and CS22 may be connected with a string selection line SSL2b, and the string selection transistors SSTa of the cell strings CS21 and CS22 may be connected with a string selection line SSL2a.

Ground selection transistors placed at the same height and the same row from among the ground selection transistors GSTa and GSTb of the plurality of cell strings CS11, CS12, CS21, and CS22 may share the same ground selection line. The ground selection transistors GSTb of the cell strings CS11 and CS12 may be connected with a ground selection line GSL1b, and the ground selection transistors GSTa of the cell strings CS11 and CS12 may be connected with a ground selection line GSL1a. The ground selection transistors GSTb of the cell strings CS21 and CS22 may be connected with a ground selection line GSL2b, and the ground selection transistors GSTa of the cell strings CS21 and CS22 may be connected with a ground selection line GSL2a.

The memory block BLK illustrated in FIG. 4 is an example, and the number of cell strings may increase or decrease, and the number of rows of cell strings and the number of columns of cell strings may increase or decrease depending on the number of cell strings. Also, in the memory block BLK, the number of cell transistors may increase or decrease, the height of the memory block BLK may increase or decrease depending on the number of cell transistors, and the number of lines connected with the cell transistors may increase or decrease depending on the number of cell transistors.

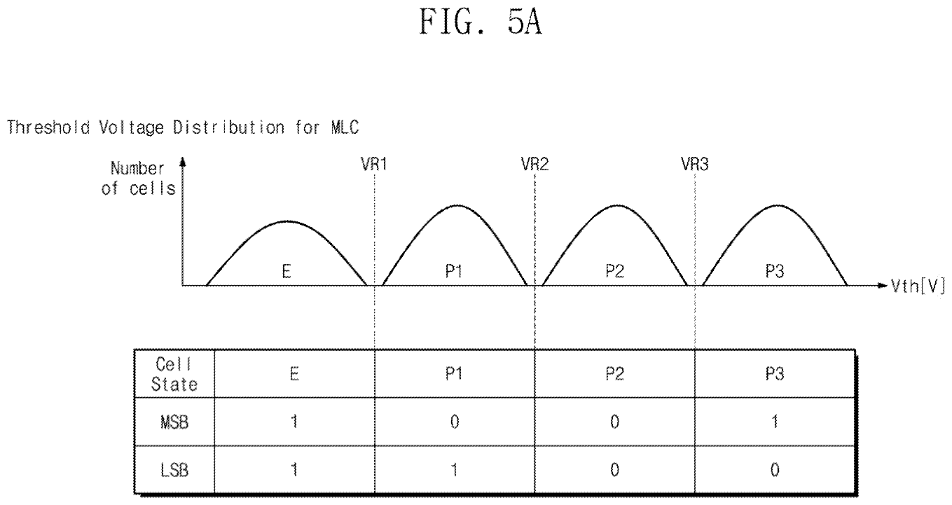

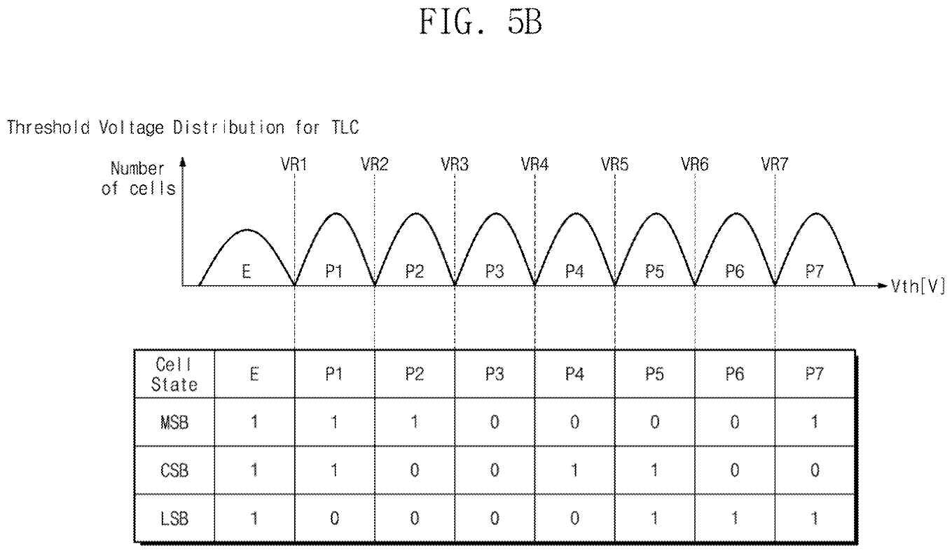

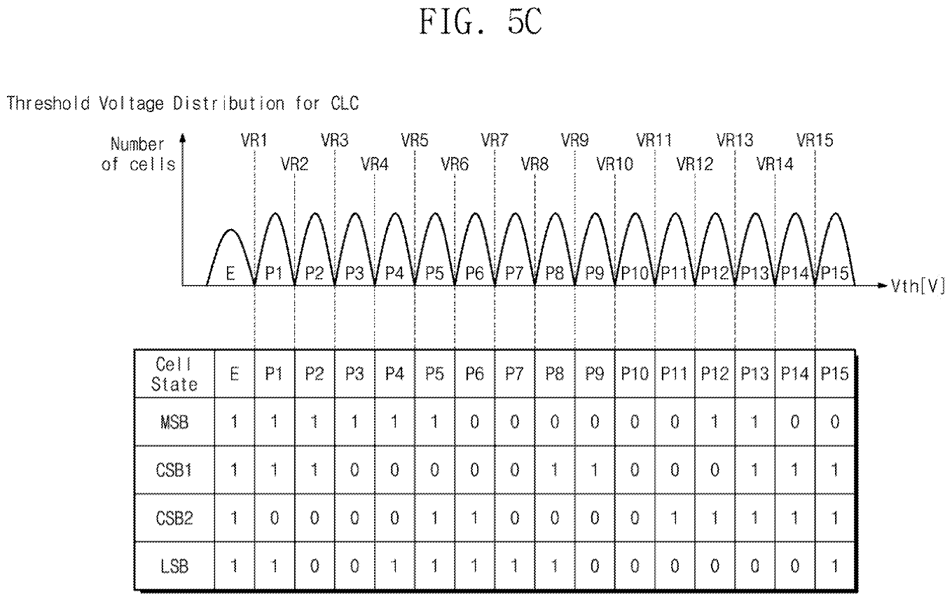

In an example embodiment, the memory block BLK may include a plurality of memory pages. The first memory cells MC1 of the cell strings CS11, CS12, CS21, and CS22 connected with the first word lines WL1 may be referred to as a “first physical page”. In an example embodiment, one physical page may correspond to a plurality of logical pages. For example, in the case where a memory cell is a triple level cell (TLC) storing information corresponding to 3 bits, a physical page may correspond to 3 logical pages. A multi-level cell storing two or more bits will be described in more detail with reference to FIGS. 5A, 5B, and 5C.

Referring again to FIGS. 1 and 3, the page buffer 125 may be connected with the memory cell array 124 through bit lines BL. The page buffer 125 may read data from the memory cell array 124 in units of page, by sensing voltages of the bit lines BL.

The column decoder 126 may receive the column address ADDC from the control logic 121. The column decoder 126 may decode the column address ADDC and may provide the data read by the page buffer 125 to the I/O circuit 127 based on a decoding result. The column decoder 126 may receive data from the I/O circuit 127 through data lines DL. The column decoder 126 may receive the column address ADDC from the control logic 121. The column decoder 126 may decode the column address ADDC and may provide the data read from the I/O circuit 127 to the page buffer 125 based on a decoding result. The page buffer 125 may store the data provided from the I/O circuit 127 in the memory cell array 124 through the bit lines BL in units of page.

The I/O circuit 127 may be connected with the column decoder 126 through the data lines DL. The I/O circuit 127 may provide data received from the storage controller 110 to the column decoder 126 through the data lines DL. The I/O circuit 127 may output data received through the data lines DL to the storage controller 110.

In an example embodiment, the address ADD, the command CMD, and the data described with reference to FIG. 3 may be transmitted/received through the non-volatile memory interface circuit 119 of the storage controller 110 of FIG. 2.

FIG. 5A is a diagram illustrating threshold voltage distributions for multi-level cells, according to an example embodiment.

Below, for convenience of description, the multi-level cell MLC refers to a memory cell storing 2 bits, a memory cell storing 3 bits is referred to as a “triple level cell TLC”, and a memory cell storing 4 bits is referred to as a “quadruple level cell QLC”.

A graph of threshold voltage distributions of multi-level cells MLC storing 2 bits and a bit table for each page corresponding to the threshold voltage distributions are illustrated in FIG. 5A. In the graph in FIG. 5A of the multi-level cell MLC, a horizontal axis represents a threshold voltage (e.g., a level of a threshold voltage), and a vertical axis represents the number of cells.

The multi-level cell MLC may have one of an erase state “E”, a first programming state P1, a second programming state P2, and a third programming state P3. In the first through third programming states P1˜P3, threshold voltage distributions sequentially increase.

In the multi-level cell MLC, a first read voltage VR1 may be a voltage for distinguishing the erase state “E” from the first programming state P1. A second read voltage VR2 may be a voltage for distinguishing the first programming state P1 from the second programming state P2. A third read voltage VR3 may be a voltage for distinguishing the second programming state P2 from the third programming state P3.

Referring to the table in FIG. 5A of the multi-level cell MLC, a most significant bit MSB and a least significant bit LSB according to a cell state are illustrated. A physical page corresponding to the multi-level cell MLC storing 2 bits may correspond to a first logical page and a second logical page. In the multi-level cell MLC, the first logical page may indicate the most significant bit MSB, and the second logical page may indicate the least significant bit LSB.

In an example embodiment, a read voltage for the multi-level cell MLC may correspond to one of a plurality of logical pages. For example, in the multi-level cell MLC, a read operation corresponding to the first logical page may be performed based on the first read voltage VR1 and the third read voltage VR3. A read operation corresponding to the second logical page may be performed based on the second read voltage VR2.

FIG. 5B is a diagram illustrating threshold voltage distributions for triple level cells, according to an example embodiment.

A graph of threshold voltage distributions of the triple level cells TLC storing 3 bits and a bit table for each page corresponding to the threshold voltage distributions are illustrated in FIG. 5B. In the graph of FIG. 5B of the triple level cell TLC, a horizontal axis represents a threshold voltage (e.g., a level of a threshold voltage), and a vertical axis represents the number of cells.

The triple level cell TLC may have one of an erase state “E”, a first programming state P1, a second programming state P2, a third programming state P3, a fourth programming state P4, a fifth programming state P5, a sixth programming state P6, and a seventh programming state P7. In the first to seventh programming states P1—P7, threshold voltage distributions sequentially increase.

In the triple level cell TLC, a first read voltage VR1 may be a voltage for distinguishing the erase state “E” from the first programming state P1. Likewise, each of second to seventh read voltages VR2 to VR7 may be a voltage for distinguishing each of the second to seventh programming states P2 to P7 from a previous state (i.e., an immediately previous state having a low threshold voltage distribution).

Referring to the table in FIG. 5B of the triple level cell TLC, a most significant bit MSB, a center significant bit CSB, and a least significant bit LSB according to a cell state are illustrated. A physical page corresponding to the triple level cell TLC storing 3 bits may correspond to a first logical page, a second logical page, and a third logical page. In the triple level cell TLC, the first logical page may indicate the most significant bit MSB, the second logical page may indicate the center significant bit CSB, and the third logical page may indicate the least significant bit LSB.

In an example embodiment, a read voltage for the triple level cell TLC may correspond to one of a plurality of logical pages. For example, in the triple level cell TLC, a read operation corresponding to the first logical page may be performed based on the third read voltage VR3 and the seventh read voltage VR7. A read operation corresponding to the second logical page may be performed based on the second read voltage VR2, the fourth read voltage VR4, and the sixth read voltage VR6. A read operation corresponding to the third logical page may be performed based on the first read voltage VR1 and the fifth read voltage VR5.

FIG. 5C is a diagram illustrating threshold voltage distributions for quadruple level cells, according to an example embodiment.

A graph of threshold voltage distributions of the quadruple level cells QLC storing 4 bits and a bit table for each page corresponding to the threshold voltage distributions are illustrated in FIG. 5C. In the graph of FIG. 5C of the quadruple level cell QLC, a horizontal axis represents a threshold voltage (e.g., a level of a threshold voltage), and a vertical axis represents the number of cells.

The quadruple level cell QLC may have one of an erase state “E”, a first programming state P1, a second programming state P2, a third programming state P3, a fourth programming state P4, a fifth programming state P5, a sixth programming state P6, a seventh programming state P7, an eighth programming state P8, a ninth programming state P9, a tenth programming state P10, an eleventh programming state P11, a twelfth programming state P12, a thirteenth programming state P13, a fourteenth programming state P14, and a fifteenth programming state P15. In the first through fifteenth programming states P1˜P15, threshold voltage distributions sequentially increase.

In the quadruple level cell QLC, a first read voltage VR1 may be a voltage for distinguishing the erase state “E” from the first programming state P1. Likewise, each of second to fifteenth read voltages VR2 to VR15 may be a voltage for distinguishing each of the second to fifteenth programming states P2 to P15 from a previous state (i.e., an immediately previous state having a low threshold voltage distribution).

Referring to the table of FIG. 5C of the quadruple level cell QLC, a most significant bit MSB, a first center significant bit CSB1, a second center significant bit CSB2, and a least significant bit LSB according to a cell state are illustrated. A physical page corresponding to the quadruple level cell QLC storing 4 bits may correspond to a first logical page, a second logical page, a third logical page, and a fourth logical page. In the quadruple level cell QLC, the first logical page may indicate the most significant bit MSB, the second logical page may indicate the first center significant bit CSB1, the third logical page may indicate the second center significant bit CSB2, and the fourth logical page may indicate the least significant bit LSB.

In an example embodiment, a read voltage for the quadruple level cell QLC may correspond to one of a plurality of logical pages. For example, in the quadruple level cell QLC, a read operation corresponding to the first logical page may be performed based on the sixth read voltage VR6, the twelfth read voltage VR12, and the fourteenth read voltage VR14. A read operation corresponding to the second logical page may be performed based on the third read voltage VR3, the eighth read voltage VR8, the tenth read voltage VR10, and the thirteenth read voltage VR13. A read operation corresponding to the third logical page may be performed based on the first read voltage VR1, the fifth read voltage VR5, the seventh read voltage VR7, and the eleventh read voltage VR11. A read operation corresponding to the fourth logical page may be performed based on the second read voltage VR2, the fourth read voltage VR4, the ninth read voltage VR9, and the fifteenth read voltage VR15.

States and read voltages of the multi-level cell MLC, the triple level cell TLC, and the quadruple level cell QLC are described above with reference to FIGS. 5A, 5B, and 5C, but read voltages corresponding to logical pages may be variously changed or modified, and one memory cell may store five or more bits.

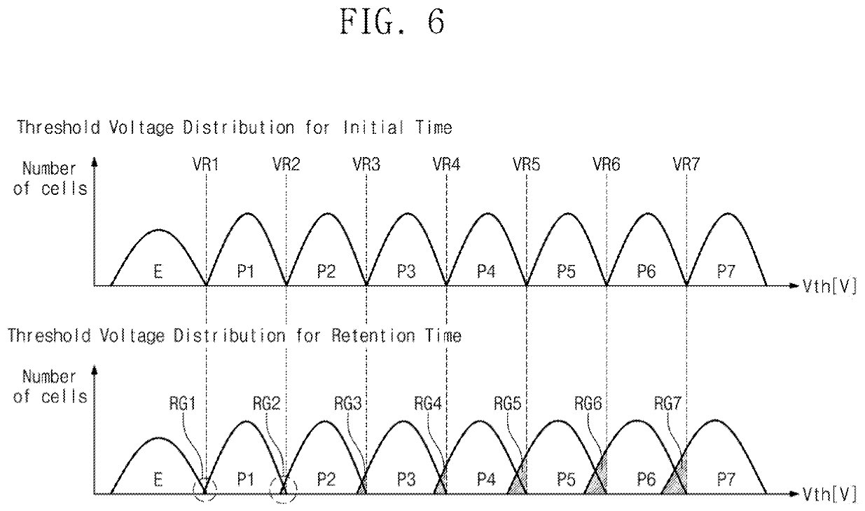

FIG. 6 is a diagram illustrating threshold voltage distributions of an initial time and a retention time, according to an example embodiment.

In the graphs of FIG. 6, a horizontal axis represents a threshold voltage, and a vertical axis represents the number of memory cells. For convenience of description, there are illustrated threshold voltage distributions of the initial time and the retention time, which are associated with the triple level cell TLC.

The initial time may mean a time point at which a bit is programmed at a memory cell through a write operation or a time within a given short time period from the time point (hereinafter referred to as a “programmed time point”) at which the bit is programmed.

The retention time may mean a time point at which a considerable time passes from the time point at which the bit is programmed at the memory cell through the write operation. The retention time is not limited to a specific time point.

As a time passing from the programmed time point increases, the degree by which a threshold voltage distribution is changed may increase.

Referring to the graph in FIG. 6 illustrating the threshold voltage distributions of the initial time, a memory cell being the triple level cell TLC may have one of the erase state “E” and the first to seventh programming states P1 to P7. At the initial time, the erase state “E” and the first to seventh programming states P1 to P7 may be distinguished from each other by the first to seventh read voltages VR1 to VR7.

Referring to the graph in FIG. 6 illustrating the threshold voltage distributions of the retention time, a threshold voltage distribution of a memory cell being the triple level cell TLC may be lower than the corresponding threshold voltage distribution of the initial time. At the initial time, memory cells corresponding to a first region RG1 from among memory cells programmed to the first programming state P1 may have a threshold voltage of the erase state “E”. Likewise, at the initial time, memory cells corresponding to each of second to seventh regions RG2 to RG7 from among memory cells programmed to each of the second to seventh programming states P2 to P7 may have a threshold voltage of a previous state (i.e., an immediately previous state having a low threshold voltage distribution). However, after a considerable time passes from a time when memory cells are programmed, threshold voltages of the memory cells may decrease due to a leakage current. Variations of threshold voltage distributions may cause the reduction of reliability of data stored in a non-volatile memory device. As the variation of the threshold voltage distribution becomes greater, an uncorrectable error may occur more frequently. To address this issue, there may be employed a read retry operation, in which a read operation is again performed after changing a read voltage.

In an example embodiment, the degree by which a threshold voltage distribution is decreased may increase as a threshold voltage becomes greater. The degree by which a threshold voltage distribution of the seventh programming state P7 becomes lower than the seventh read voltage VR7 may correspond to the seventh region RG7. The degree by which a threshold voltage distribution of the sixth programming state P6 becomes lower than the sixth read voltage VR6 may correspond to the sixth region RG6. The seventh region RG7 may be wider than the sixth region RG6. Likewise, the second to sixth regions RG2 to RG6 may be wider than the first to fifth regions RG1 to RG5.

A general storage controller may adjust the highest read voltage (e.g., having the highest voltage level) of a plurality of read voltages for identifying bit values of one logical page. The general storage controller may count the number of memory cells having the first bit value from among memory cells each having the first bit value or the second bit value, in units of logical page. The general storage controller may adjust a read voltage based on a value thus counted. However, because the counted value is determined based on all read voltages corresponding to one logical page, it may be difficult to simultaneously adjust all the read voltages based on the counted value. As such, there may be considered a way to selectively adjust only a read voltage having the greatest influence on the reduction of reliability from among a plurality of read voltages corresponding to one logical page.

In detail, the degree by which a threshold voltage distribution (e.g., a voltage level of a threshold voltage distribution) for identifying a logical page is decreased may increase as a threshold voltage becomes greater. Thus, it may be more suitable to adjust a read voltage for determining a programming state corresponding to a high threshold voltage than to adjust a read voltage for determining a programming state corresponding to a low threshold value. Accordingly, the storage controller 110 may adjust the highest read voltage of a plurality of read voltages corresponding to one logical page.

For example, referring to FIG. 5A, in the case of performing read retry on the multi-level cell MLC storing 2 bits, the storage controller 110 may adjust the third read voltage VR3 of the first and third read voltages VR1 and VR3 corresponding to the first logical page indicating the most significant bit MSB. The storage controller 110 may adjust the second read voltage VR2 corresponding to the second logical page indicating the least significant bit LSB.

As another example, referring to FIG. 5B, in the case of performing read retry on the triple level cell TLC storing 3 bits, the storage controller 110 may adjust the seventh read voltage VR7 of the third and seventh read voltages VR3 and VR7 corresponding to the first logical page indicating the most significant bit MSB. The storage controller 110 may adjust the sixth read voltage VR6 of the second, fourth, and sixth read voltages VR2, VR4, and VR6 corresponding to the second logical page indicating the center significant bit CSB. The storage controller 110 may adjust the fifth read voltage VR5 of the first and fifth read voltages VR1 and VR5 corresponding to the third logical page indicating the least significant bit LSB.

As another example, referring to FIG. 5C, in the case of performing read retry on the quadruple level cell QLC storing 4 bits, the storage controller 110 may adjust the fourteenth read voltage VR14 of the sixth, twelfth, and fourteenth read voltages VR6, VR12, and VR14 corresponding to the first logical page indicating the most significant bit MSB. The storage controller 110 may adjust the thirteenth read voltage VR13 of the third, eighth, tenth, and thirteenth read voltages VR3, VR8, VR10, and VR13 corresponding to the second logical page indicating the first center significant bit CSB1. The storage controller 110 may adjust the eleventh read voltage VR11 of the first, fifth, seventh, and eleventh read voltages VR1, VR5, VR7, and VR11 corresponding to the third logical page indicating the second center significant bit CSB2. The storage controller 110 may adjust the fifteenth read voltage VR15 of the second, fourth, ninth, and fifteenth read voltages VR2, VR4, VR9, and VR15 corresponding to the fourth logical page indicating the least significant bit LSB.

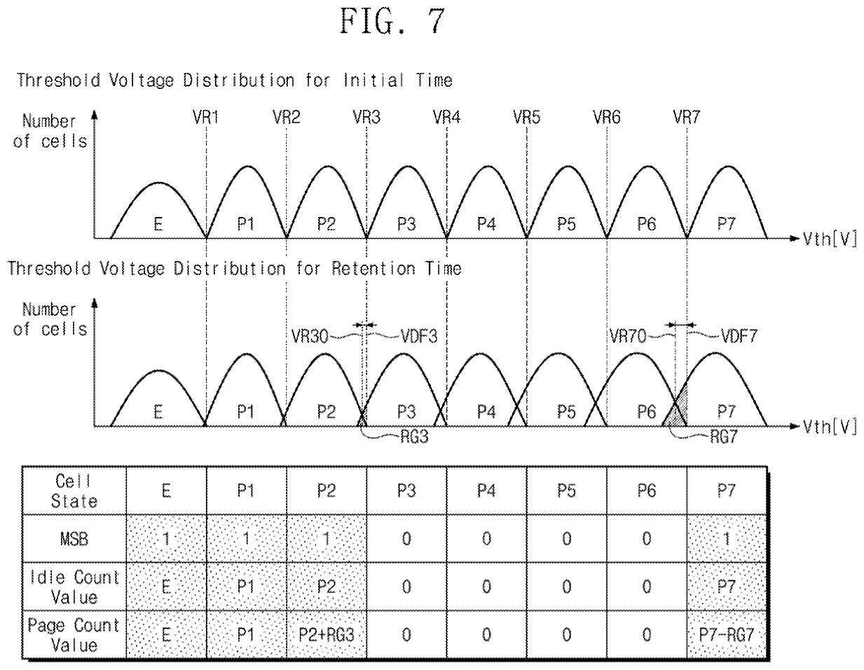

FIG. 7 is a diagram for describing a page count value according to an example embodiment.

A page count value corresponding to the first logical page of the triple level cell TLC, which indicates the most significant bit MSB, will be described with reference to FIG. 7. The first logical page of the triple level cell TLC, which indicates the most significant bit MSB, will be described for better understanding.

For better understanding of the page count value, a graph of threshold voltage distributions of an initial time and a graph of threshold voltage distributions of a retention time are illustrated. In the graphs of FIG. 7, a horizontal axis represents a threshold voltage, and a vertical axis represents the number of memory cells.

Referring to the graphs in FIG. 7, memory cells corresponding to the third region RG3 may be programmed to have the third programming state P3 at the initial time, but may have threshold voltages lower than the third read voltage VR3 at the retention time. In the case of changing the third read voltage VR3 to a third optimized read voltage VR3O at the retention time, an error level of data read from the memory cells may decrease. The third optimized read voltage VR3O may be a voltage being a criterion for halving memory cells of the second programming state P2 and memory cells of the third programming state P3 at the retention time. The third optimized read voltage VR3O may be lower than the third read voltage VR3 by as much as a third voltage difference VDF3.

An error due to the memory cells of the second programming state P2, which have threshold voltages higher than the third optimized read voltage VR3O, and an error due to the memory cells of the third programming state P3, which have threshold voltages lower than the third optimized read voltage VR3O, may be repaired by error correction of the ECC engine 117.

Likewise, memory cells corresponding to the seventh region RG7 may be programmed to have the seventh programming state P7 at the initial time, but may have threshold voltages lower than the seventh read voltage VR7 at the retention time. In the case of changing the seventh read voltage VR7 to a seventh optimized read voltage VR7O at the retention time, an error level of data read from the memory cells may decrease. The seventh optimized read voltage VR7O may be a voltage being a criterion for halving memory cells of the sixth programming state P6 and memory cells of the seventh programming state P7 at the retention time. The seventh optimized read voltage VR7O may be lower than the seventh read voltage VR7 by as much as a seventh voltage difference VDF7.

An error due to the memory cells of the sixth programming state P6, which have threshold voltages higher than the seventh optimized read voltage VR7O, and an error due to the memory cells of the seventh programming state P7, which have threshold voltages lower than the seventh optimized read voltage VR7O, may be repaired by error correction of the ECC engine 117.

A cell state, the most significant bit MSB, an idle count value, and a page count value associated with the triple level cell TLC will be described with reference to the table of FIG. 7.

In the first logical page indicating the most significant bit MSB of the triple level cell TLC, at the initial time, the erase state “E” and the first, second, and seventh programming states P1, P2, and P7 may have the first bit value (e.g., bit value “1”). In the first logical page indicating the most significant bit MSB of the triple level cell TLC, at the initial time, the third, fourth, fifth, and sixth programming states P3, P4, P5, and P6 may have the second bit value (e.g., bit value “0”).

The storage controller 110 may count the number of memory cells having the first bit value at the initial time to determine the idle count value. The idle count value may be variable for every logical page, and a logical page may correspond to at least one read voltage. The first logical page indicating the most significant bit MSB of the triple level cell TLC may correspond to the third read voltage VR3 and the seventh read voltage VR7.

In this case, the idle count value may indicate the number of memory cells having the first bit value, which is counted based on the third and seventh read voltages VR3 and VR7 at the initial time. In more detail, the idle count value may be a sum of the number of memory cells having the erase state “E”, the number of memory cells having the first programming state P1, the number of memory cells having the second programming state P2, and the number of memory cells having the seventh programming state P7.

The storage controller 110 may count the number of memory cells having the first bit value at the retention time to determine the page count value. Like the idle count value, the page count value may be variable every logical page, and a logical page may correspond to at least one read voltage.

For example, in the case of the first logical page indicating the most significant bit MSB of the triple level cell TLC, the page count value may indicate the number of memory cells having the first bit value, which is counted based on the third and seventh read voltages VR3 and VR7 at the retention time.

In more detail, the page count value may be a sum of a first value and a second value: the first value obtained by adding the number of memory cells having the erase state “E”, the number of memory cells having the first programming state P1, the number of memory cells having the second programming state P2, and the number of memory cells corresponding to the third region RG3, and the second value obtained by subtracting the number of memory cells corresponding to the seventh region RG7 from the number of memory cells having the seventh programming state P7.

In an example embodiment, at the retention time, the page count value that is based on a read voltage before optimization may have a correlation with the optimized read voltage. The storage controller 110 may optimize a read voltage based on a difference between the idle count value and the page count value.

For example, at a test level, the storage controller 110 may experimentally obtain an optimized read voltage corresponding to the difference between the idle count value and the page count value. At a usage level, the storage controller 110 may change a read voltage to an optimized read voltage obtained in advance, based on the difference between the idle count value and the page count value. In the case where a plurality of read voltages are associated with one logical page, it may be difficult to optimize all the read voltages associated with the logical page, and the storage controller 110 may attempt only optimization of the highest read voltage.

The difference between the idle count value and the page count value may correspond to a value obtained by subtracting the number of memory cells of the third region RG3 from the number of memory cells of the seventh region RG7. The storage controller 110 may store the difference between the idle count value and the page count value so as to correspond to the seventh voltage difference VDF7. When the difference between the idle count value and the page count value at the retention time corresponds to a value obtained by subtracting the number of memory cells of the third region RG3 from the number of memory cells of the seventh region RG7, the storage controller 110 may determine the seventh optimized read voltage VR7O by decreasing the seventh read voltage VR7 as much as the seventh voltage difference VDF7. In this case, the third read voltage VR3 may not be optimized.

In the case where data read by the DMA read operation of the storage controller 110 is determined as having an uncorrectable error, the retention time may be a time point at which the storage controller 110 reads data through the DMA read operation. The storage controller 110 may generate a value of counting the number of memory cells having the first bit value as information accompanied every DMA read operation and may store the counted value in a DMA register. When an uncorrectable error is detected, the storage controller 110 may regard, as the retention time, a time point at which the DMA read operation is performed, and may attempt the optimization of a read operation.

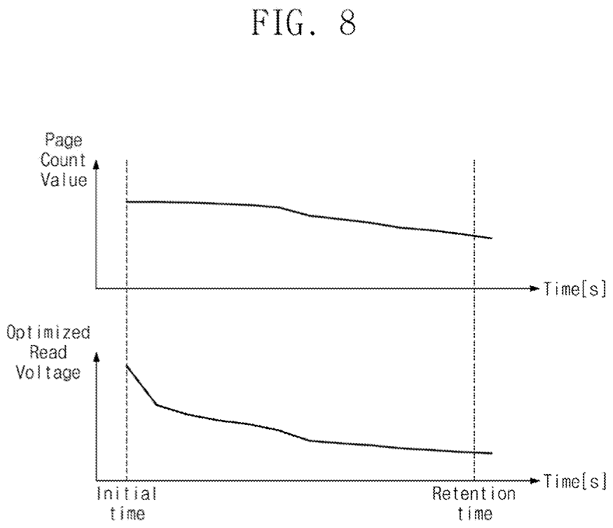

FIG. 8 is a diagram illustrating a page count value and an optimized read voltage according to an example embodiment.

Referring to FIG. 8, a graph of a page count value and a graph of an optimized read voltage are illustrated. In the graph of the page count value, a horizontal axis represents a time, and a vertical axis represents the page count value. In the graph of the optimized read voltage, a horizontal axis represents a time, and a vertical axis represents the optimized read voltage.

Referring to the graph in FIG. 8 of the page count value, the page count value at the retention time may be smaller than the page count value at the initial time. Thus, the page count value may have the tendency of decreasing as a time passes.

Referring to the graph in FIG. 8 of the optimized read voltage, the optimized read voltage at the retention time may be lower than the optimized read voltage at the initial time. Thus, the optimized read voltage may have the tendency of decreasing as a time passes.

In an example embodiment, a storage controller 110 may obtain optimized read voltages that respectively correspond to page count values at a plurality of retention times while adjusting a retention time at a test level. When an uncorrectable error occurs in a read operation, the storage controller 110 may perform read retry based on an optimized read voltage corresponding to a page count value.

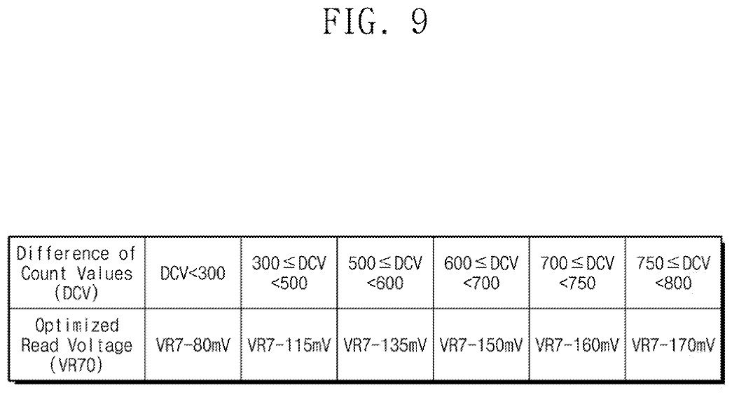

FIG. 9 is a table illustrating a relationship between page count values and optimized read voltages, according to an example embodiment.

Referring to FIG. 9, a relationship between a difference of count values DCV and an optimized read voltage VR7O is illustrated as a table. For better understanding, an example where the seventh read voltage VR7 associated with the first logical page indicating the most significant bit MSB of the triple level cell TLC is optimized will be described.

The difference of count values DCV may have a value obtained by subtracting a page count value from an idle count value. The idle count value (a value obtained by counting the number of first bit values at the initial time) may be uniform. The page count value may be a value obtained by counting the number of first bit values at the retention time. As a long retention time passes from the initial time, the page count value may decrease. The difference of count values DCV may increase along the degree by which the retention time passes.

The seventh optimized read voltage VR7O may have a value obtained by subtracting the seventh voltage difference VDF7 from the seventh read voltage VR7 at the initial time. As a long retention time passes from the initial time, the seventh voltage difference VDF7 may increase, and the seventh optimized read voltage VR7O may decrease.

A relationship between the difference of count values DCV and the seventh optimized read voltage VR7O is illustrated in the table of FIG. 9 by way of example, but sections to which the difference of count values DCV belongs may be changed depending on characteristics of the design and material of a storage device, and optimized read voltages corresponding to the sections may increase or decrease.

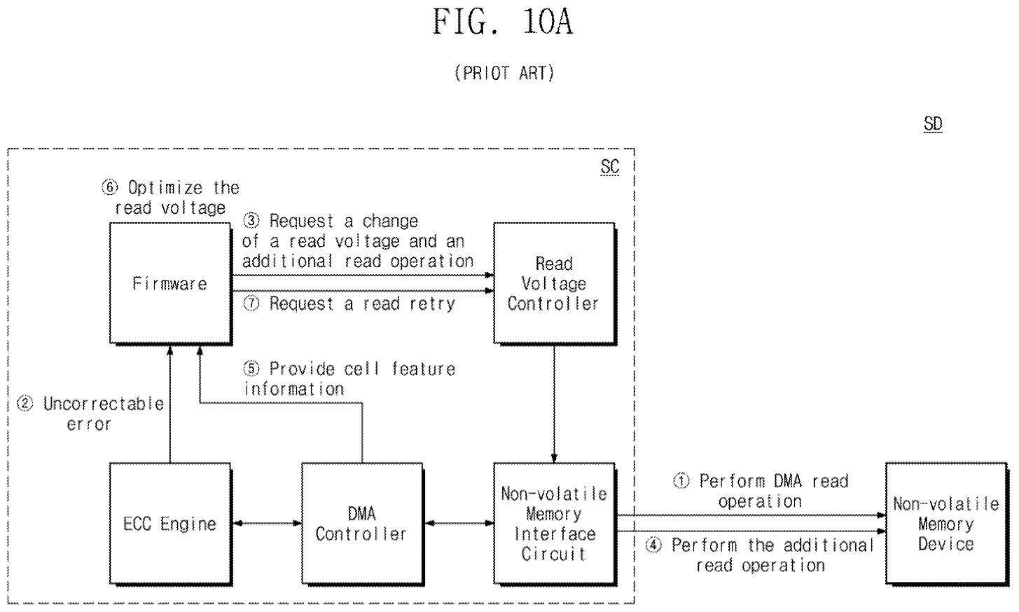

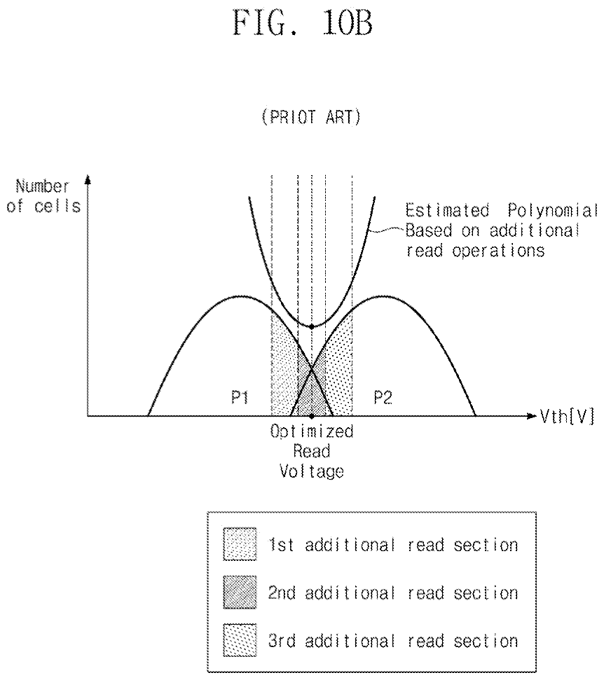

FIG. 10A is a block diagram for describing read retry of a general storage device SD according to the prior art. FIG. 10B is a diagram for describing an additional read operation for read retry of a general storage device according to the prior art.

Read retry of a general storage device SD according to the prior art will be described with reference to FIGS. 10A and 10B. Below, the prior art is intended to describe a part of the prior art, which is contrasted with the present disclosure, by way of example, and is not intended to concede all characteristics of drawings marked by “PRIOR ART” as the prior art or to deny a difference of the present disclosure by these characteristics.

The general storage device SD may include a non-volatile memory device and a general storage controller SC.

The non-volatile memory device may store data.

The general storage controller SC may communicate with the non-volatile memory device. The general storage controller SC may include a DMA controller, firmware, a read voltage controller, an ECC engine, and a non-volatile memory interface circuit.

The DMA controller may perform a DMA read operation on data stored in the non-volatile memory device through the non-volatile memory interface circuit. The DMA controller may output the read raw data to the ECC engine. The ECC engine may perform error correction on the raw data. When an error level of the raw data exceeds an error correction capability of the ECC engine, the ECC engine may determine an error of the raw data as uncorrectable. The ECC engine may be managed by the firmware.

The firmware may request the read voltage controller to change a read voltage and to perform an additional read operation, based on that an error uncorrectable by the ECC engine occurs. Here, the additional read operation may mean a read operation for measuring threshold voltage distributions of memory cells, not read retry using an optimized read voltage. A change of a read voltage may mean a voltage change for the additional read voltage, not a change to an optimized read voltage.

The read voltage controller may change a read voltage of the non-volatile memory device through the non-volatile memory interface circuit. The DMA controller may perform the additional read operation, which is based on the read voltage changed at the non-volatile memory device, through the non-volatile memory interface circuit. The DMA controller may provide cell feature information to the firmware based on the additional read operation. The cell feature information may include a value obtained by counting the number of first bit values by using the changed read voltage. The cell feature information may indicate threshold voltage distributions at a point in time when the additional read operation is performed.

The firmware may optimize a read voltage based on the cell feature information received from the DMA controller.

For example, referring to FIG. 10B, at the retention time when a considerable time passes from the initial time, a threshold voltage distribution of memory cells of the second programming state P2 may decrease. The general storage controller SC may perform additional read operations in first, second, and third additional read sections, respectively, and may obtain the cell feature information indicating the number of cells for each section. The firmware may estimate a polynomial by using the cell feature information obtained through the additional read operations. The firmware may determine a threshold voltage corresponding to a value of the estimated polynomial, at which the number of memory cells is minimum, as an optimized read voltage.

The firmware may request the read retry from the read voltage controller and the DMA controller, based on the optimized read voltage. For example, the firmware may request the read voltage controller to change a read voltage to the optimized read voltage. After the read voltage is changed to the optimized read voltage, the firmware may request the DMA controller to perform the DMA read operation.

As described above, after an uncorrectable error is detected, the general storage device SD according may perform additional read operations to obtain cell feature information. An operating speed of the general storage device SD may be reduced due to the additional read operation requiring the following: a change of a read voltage, execution of additional read operations, and polynomial estimation.

FIG. 11 is a block diagram for describing read retry of a storage device according to an example embodiment.

Read retry of the storage device 100 according to an example embodiment will be described with reference to FIG. 11.

The storage device 100 may include the storage controller 110 and the non-volatile memory device 120.

The storage controller 110 may include the firmware 116 and a read voltage control unit RCU.

The read voltage control unit RCU may include the DMA controller 111, the DMA register 112, the read voltage controller 113, the ECC engine 117, and the non-volatile memory interface circuit 119.

The DMA controller 111 may perform the DMA read operation on data stored in the non-volatile memory device 120 through the non-volatile memory interface circuit 119. The DMA controller 111 may count the number of memory cells having the first bit value from read raw data in units of logical page and may update a page count value of the DMA register 112.

In this case, the operation of counting the number of memory cells having the first bit value in units of logical page is an operation accompanied by the DMA read operation and may hardly reduce a data processing speed of the storage controller 110. Thus, the DMA controller 111 may generate the page count value being a byproduct of the DMA read operation and may store the page count value in the DMA register 112.

The DMA controller 111 may output the raw data read through the non-volatile memory interface circuit 119 to the ECC engine 117.

The ECC engine 117 may perform error correction on the raw data. When an error level of the raw data exceeds an error correction capability of the ECC engine 117, the ECC engine 117 may determine an error of the raw data as uncorrectable. The ECC engine 117 may be managed by the firmware 116.

The firmware 116 may prepare the read retry, based on that the error uncorrectable by the ECC engine 117 occurs.

In more detail, based on that the error uncorrectable by the ECC engine 117 occurs, the firmware 116 may refer to the page count value stored in the DMA register 112. The page count value may include feature information of the memory cells (e.g., a threshold voltage distribution at a point in time when the DMA read operation is performed). The firmware 116 may optimize a read voltage based on the page count value.

In an example embodiment, through the firmware 116, the storage controller 110 may optimize the read voltage based on the idle count value and the page count value. The firmware 116 may optimize the read voltage, based on a difference between an idle count value of an initial time and a page count value of a retention time when there is performed the DMA read operation in which the uncorrectable error occurs.

Unlike the case of FIG. 10B in which a plurality of additional read operations are performed and a minimum value is obtained from a polynomial estimated by using cell feature information obtained through the additional read operations, in the present example embodiment the storage controller 110 may determine a corresponding optimized read voltage based on a page count value. Thus, because the additional read operations for obtaining the cell feature information are omitted, a speed at which the storage controller 110 performs the read retry may be improved.

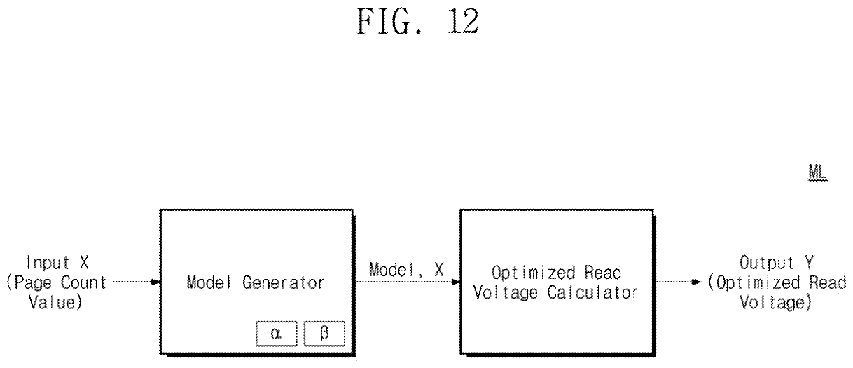

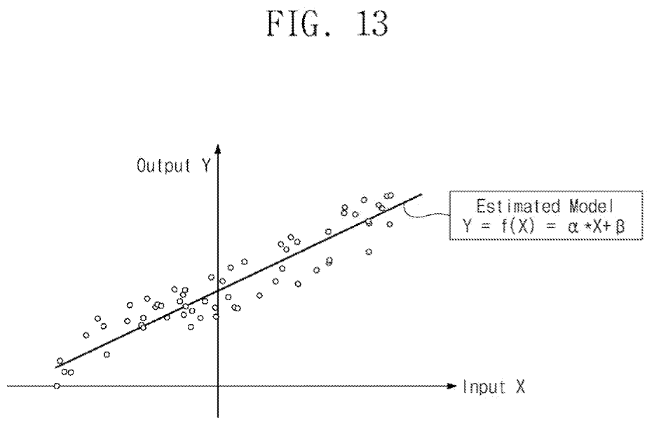

In an example embodiment, through the firmware 116, the storage controller 110 may determine an optimized read voltage by using a machine learning device ML device. The machine learning device ML may generate a machine learning model for generating an optimized read voltage. The machine learning device ML may calculate the optimized read voltage based on the machine learning model and a page count value. The machine learning device ML will be described in more detail with reference to FIGS. 12 and 13.

The firmware 116 may request the read retry from the read voltage controller 113 and the DMA controller 111, based on the optimized read voltage. The firmware 116 may request the read voltage controller 113 to change a read voltage to the optimized read voltage. After the read voltage is changed to the optimized read voltage, the firmware 116 may request the DMA controller 111 to perform the DMA read operation.

As described above, according to an example embodiment, the storage device 100 may update a page count value generated as a byproduct every DMA read operation in the DMA register 112. When an uncorrectable error is detected, the storage device 100 may determine an optimized read voltage based on a difference between a page count value and an idle count value, which corresponds to cell feature information.

Because additional read operations for obtaining cell feature information after an uncorrectable error is detected are omitted and polynomial estimation for each read section is omitted by using a difference between a page count value and an idle count value, the storage device 100 may provide an improved data processing speed and improved reliability.

FIG. 12 is a block diagram illustrating a machine learning device ML of FIG. 11, according to an example embodiment. FIG. 13 is a diagram illustrating a machine learning model created by a model creator of FIG. 12, according to an example embodiment.

The machine learning device ML included in the firmware 116 will be described with reference to FIGS. 11, 12, and 13.

For better understanding, the machine learning device ML is described as software that is included in the firmware 116 stored in a memory. The machine learning device ML may be implemented by separate hardware or a combination of hardware and software.

The machine learning device ML may receive an input “X” and may generate an output “Y”. The input “X” may be a page count value obtained with reference to the DMA register 112. The output “Y” may be an optimized read voltage. The optimized read voltage may be output to the read voltage controller 113 under control of the firmware 116.

The machine learning device ML may include a model generator and an optimized read voltage calculator.

The model generator may include a first parameter α and a second parameter β. In an example embodiment, at a test level, the model generator may determine the first parameter α and the second parameter β through a machine learning algorithm, based on a training data set being a pair of a page count value in a test process and an experimentally obtained optimized read voltage.

For example, referring to FIG. 13, a plurality of training data sets and an estimated machine learning model are illustrated. One training data set may include a pair of input “X” and output “Y”. In FIG. 13, a horizontal axis represents a magnitude of the input “X”. The input “X” may be a page count value. In FIG. 13, a vertical axis represents a magnitude of the output “Y”. The output “Y” may be an optimized read voltage.

The model generator may generate a machine learning model, in which an error (e.g., a distance between a linear graph of the estimated machine learning model and a training data set) is minimized, based on the plurality of training data sets. To generate the machine learning model may mean to determine the first parameter α and the second parameter β.

Returning to FIG. 12, the model generator may include the first parameter α and the second parameter β determined through the machine learning algorithm. The model generator may receive the input “X”. The input “X” may be a page count value. The model generator may output the machine learning model, which is based on the first parameter α and the second parameter β, and the input “X” to the optimized read voltage calculator.

The optimized read voltage calculator may input the input “X” to the machine learning model, which is based on the first parameter α and the second parameter β. The estimated machine learning model may be expressed by the following Equation:

Y=α*X+β

In the Equation above, “X” denotes an input value, “α” denotes the first parameter α of the model generator, “β” denotes the second parameter β of the model generator, and “Y” denotes an output value.

The optimized read voltage calculator may determine the output “Y” based on the machine learning model and the input “X”. The output “Y” may be an optimized read voltage.

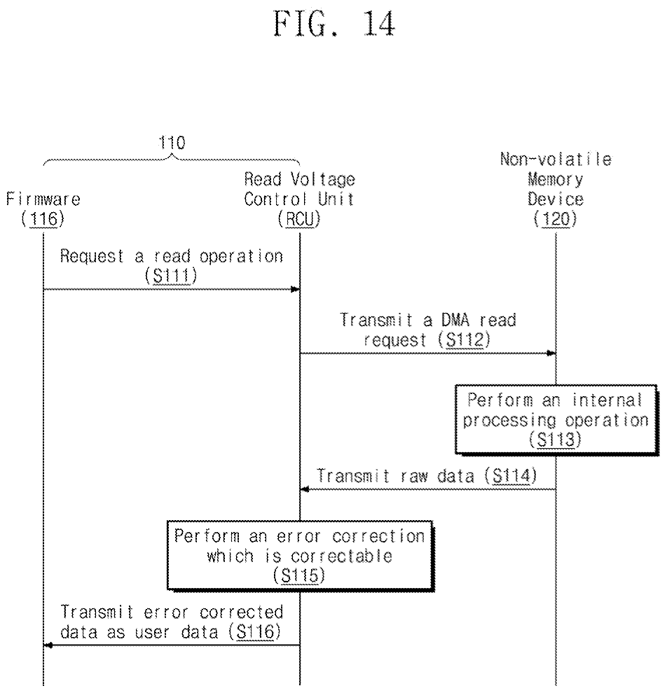

FIG. 14 is a flowchart illustrating an operating method of a storage device according to an example embodiment.

An operating method of a storage device will be described with reference to FIG. 14. The storage device may correspond to the storage device 100 of FIG. 11.

Referring to FIGS. 11 and 14, the storage device 100 may include the storage controller 110 and the non-volatile memory device 120. The storage controller 110 may include the firmware 116 and the read voltage control unit RCU.

In operation S111, the firmware 116 may request a read operation from the read voltage control unit RCU.

In operation S112, the read voltage control unit RCU may transmit a DMA read request to the non-volatile memory device 120.

In operation S113, the non-volatile memory device 120 may perform an internal processing operation based on the DMA read request. The internal processing operation may mean an operation of controlling sense amplification and preparing a data output according to the DMA read operation such as an operation of storing data in a page buffer in units of page.

In operation S114, the non-volatile memory device 120 may transmit raw data to the read voltage control unit RCU. The raw data that are data output from the non-volatile memory device 120 may mean data that do not experience error correction of an ECC engine. To transmit the raw data in operation S114 may be referred to as “performing the DMA read operation”.

In an example embodiment, the read voltage control unit RCU may count the number of memory cells having the first bit value from the raw data received in operation S114 in units of logical page and may store a page count value in a DMA register.

In operation S115, the read voltage control unit RCU may perform error correction on the raw data transmitted in operation S114. In an example embodiment, an error level of the raw data may be lower than an error correction capacity of the ECC engine of the read voltage control unit RCU. The ECC engine may correct an error of the raw data and may generate error-corrected data.

In operation S116, the read voltage control unit RCU may transmit the error-corrected data to the firmware 116 as user data. The user data may be data that do not include an error and is usable by the user. The user data may be data that have the same information as data written at the corresponding DMA write operation. The firmware 116 may output the user data to another external device (not illustrated) that performs DMA communication with the storage controller 110.

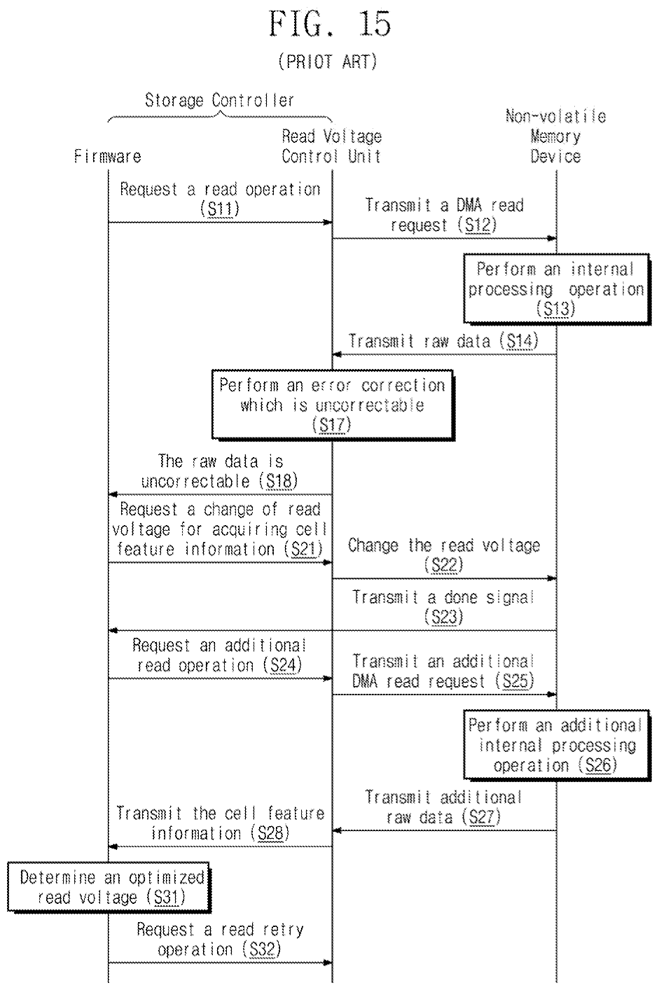

FIG. 15 is a flowchart illustrating an operating method of a general storage device according to the prior art.

The storage device referred to in connection with FIG. 15 may correspond to the general storage device of FIG. 10A.

Referring to FIGS. 10A and 15, the general storage device may include a general storage controller and a non-volatile memory device. The general storage controller may include firmware and a read voltage control unit.

In operation S11, the firmware may request a read operation from the read voltage control unit.

In operation S12, the read voltage control unit may transmit a DMA read request to the non-volatile memory device.

In operation S13, the non-volatile memory device may perform an internal processing operation based on the DMA read request.

In operation S14, the non-volatile memory device may transmit raw data according to the DMA read operation to the read voltage control unit.

In operation S17, the read voltage control unit may perform error correction. Unlike operation S115 of FIG. 14, an error of the raw data in operation S17 may be uncorrectable. For example, an error level of the raw data may exceed an error correction capacity of an ECC engine of the read voltage control unit.

In operation S18, the firmware may detect that the ECC engine fails to correct the error of the raw data.

In operation S21, the firmware may request a change of a read voltage from the read voltage control unit for the purpose of obtaining cell feature information.

In operation S22, the read voltage control unit may change a read voltage of the non-volatile memory device. In this case, the change of the read voltage may intend to change the read voltage to a read voltage, which is used in an additional read operation for obtaining cell feature information to be used for optimization, not intending a change to an optimized read voltage for the read retry.

In operation S23, the non-volatile memory device may output, to the firmware, a done signal indicating that the change of the read voltage is completed.

In operation S24, the firmware may request the read voltage control unit to perform an additional read operation using the changed voltage.

In operation S25, the read voltage control unit may transmit an additional DMA read request to the non-volatile memory device.

In operation S26, the non-volatile memory device may perform an additional internal processing operation based on the additional DMA read request.

In operation S27, the non-volatile memory device may transmit additional raw data according to the additional DMA read operation to the read voltage control unit. The additional raw data may include cell feature information.

In operation S28, the read voltage control unit may transmit the cell feature information to the firmware.

In operation S31, the firmware may determine an optimized read voltage based on the cell feature information obtained in operation S28.

In operation S32, the firmware may request a read retry operation from the read voltage control unit. The request for the read retry operation may include a request for changing a read voltage to the optimized read voltage determined in operation S31.

The read retry operation of the general storage device is described above with reference to FIG. 15. The general storage device may perform additional read operations for obtaining cell feature information after an uncorrectable error is detected, thereby causing a decrease of an operating speed of the storage device. The general storage device may further perform a series of operations S21, S22, S23, S24, S25, S26, and S27 independently of the DMA read operation, thereby causing an increase of throughput and a decrease of a data processing speed.

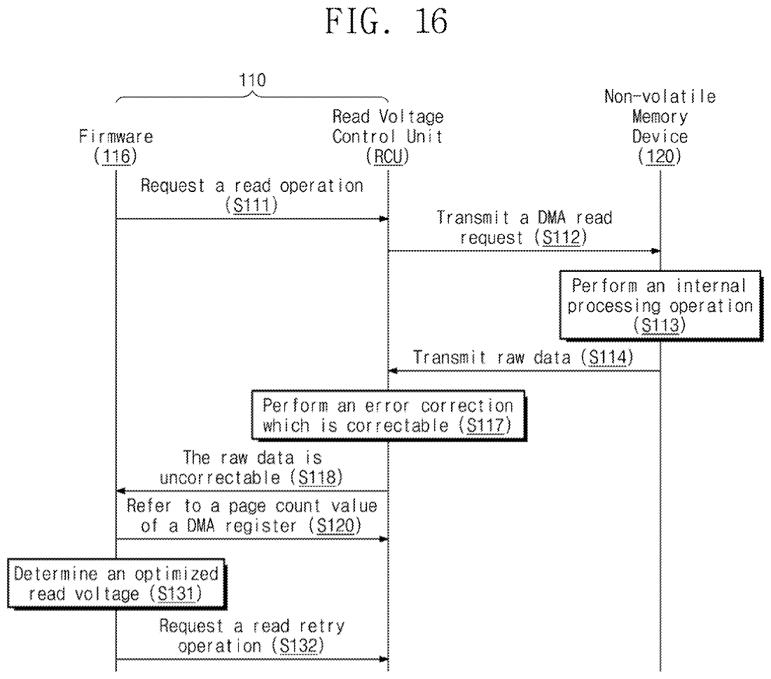

FIG. 16 is a flowchart illustrating an operating method of a storage device according to an example embodiment.

An operating method of a storage device will be described with reference to FIG. 16.

The storage device may correspond to the storage device 100 according to the example embodiment of FIG. 11.

Referring to FIGS. 11 and 16, the storage device 100 may include the storage controller 110 and the non-volatile memory device 120. The storage controller 110 may include the firmware 116 and the read voltage control unit RCU.

In FIG. 16, operation S111, operation S112, operation S113, and operation S114 are similar to operation S111, operation S112, operation S113, and operation S114 of FIG. 14, and thus, additional description will be omitted to avoid redundancy.

In operation S117, the read voltage control unit RCU may perform error correction. Unlike operation S115 of FIG. 14, an error of the raw data in operation S117 may be uncorrectable. For example, an error level of the raw data may exceed an error correction capacity of an ECC engine of the read voltage control unit RCU.

In operation S118, the firmware 116 may detect that the ECC engine of the read voltage control unit RCU fails to correct the error of the raw data.

In operation S120, the firmware 116 may refer to a page count value of a DMA register of the read voltage control unit RCU. The page count value may be a value updated by the DMA controller of the read voltage control unit RCU in operation S114. The page count value may indicate cell feature information (e.g., a threshold voltage distribution of memory cells) at a point in time when the DMA read operation according to operation S114 is performed.

In operation S131, the firmware 116 may determine an optimized read voltage based on the page count value in operation S120.

In operation S132, the firmware 116 may request the read retry operation from the read voltage control unit RCU. The request for the read retry operation may include a request for changing a read voltage to the optimized read voltage determined in operation S131.

The read retry operation of the storage device 100 according to an example embodiment is described above with reference to FIG. 16. Unlike the read retry operation of FIG. 15, because additional read operations for obtaining cell feature information are omitted, a storage device with an improved data processing speed and improved reliability may be provided.

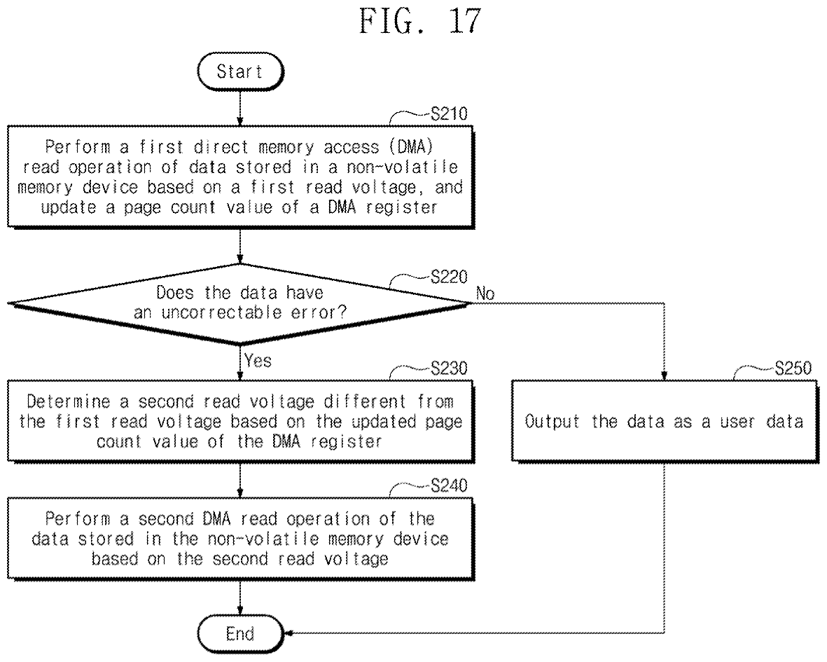

FIG. 17 is a flowchart illustrating an operating method of a storage device according to an example embodiment.

An operating method of a storage device according to embodiments will be described with reference to FIG. 17.

The storage device may correspond to the storage device 100 of FIG. 11. The storage device may include a non-volatile memory device and a storage controller. The storage controller may communicate with the non-volatile memory device.

In operation S210, the storage device may perform a first DMA read operation on data stored in the non-volatile memory device, based on a first read voltage. The storage device may update a page count value of a DMA register.

In operation S220, the storage device may determine whether data read from the non-volatile memory device include an uncorrectable error. In an example embodiment, operation S220 may include performing error correction on the data read by the first DMA read operation, and determining whether the data include an uncorrectable error, based on a result of the error correction.

When the data include an uncorrectable error, the storage device may perform operation S230.

When the data include a correctable error, the storage device may perform operation S250.

In operation S230, the storage device may determine a second read voltage different from the first read voltage in operation S210, based on the updated page count value of the DMA register. In an example embodiment, the second read voltage may be a read voltage optimized on a page corresponding to the first read voltage, based on a difference between the updated page count value and an idle count value indicating the number of memory cells having the first bit value within the corresponding page at the initial time.

In operation S240, the storage device may perform a second DMA read operation on data stored in the non-volatile memory device, based on the second read voltage. In an example embodiment, the second DMA read operation may mean the read retry operation.

In operation S250, the storage device may output data, which are determined as not including an uncorrectable error in operation S220, as user data to an external device. For example, in operation S250, the storage device may output data, on which error correction is performed in operation S220, to the external device as the user data.

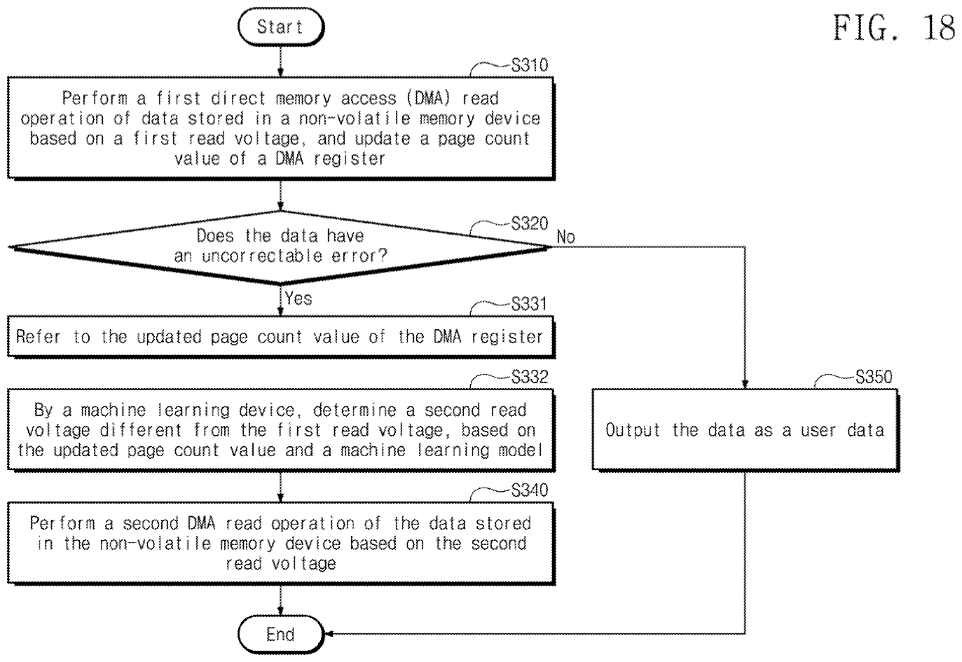

FIG. 18 is a flowchart illustrating an operating method of a storage device according to an example embodiment.

An operating method of a storage device according to embodiments will be described with reference to FIG. 18.

The storage device may correspond to the storage device 100 of FIG. 11. The storage device may include a non-volatile memory device and a storage controller. The storage controller may communicate with the non-volatile memory device.

In FIG. 18, operation S310, operation S320, operation S340, and operation S350 are similar to operation S210, operation S220, operation S240, and operation S250 of FIG. 17, and thus, additional description will be omitted to avoid redundancy.

When it is determined in operation S320 that the data include an uncorrectable error, the storage device may perform operation S331.

In operation S331, the storage device may refer to the updated page count value of the DMA register. The page count value may be a value updated by the first DMA read operation in operation S310.

In operation S332, the machine learning device of the storage device may determine the second read voltage based on the updated page count value and the machine learning model.

In an example embodiment, before performing the first DMA read operation in operation S310, the machine learning model may include a first parameter and a second parameter determined by the machine learning algorithm based on a training data set corresponding to the first read voltage.

In an example embodiment, operation S332 may include determining, by the machine learning device, a value obtained by adding the second parameter and a product of the first parameter and the updated page count value as the second read voltage. In this case, the first parameter and the second parameter may be values determined by the machine learning algorithm at a test level.

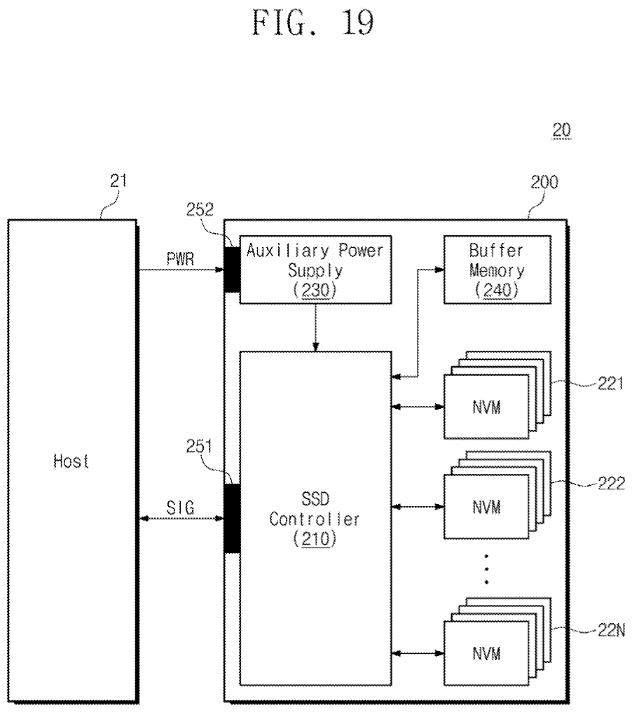

FIG. 19 is a block diagram of a solid state drive (SSD) system to which a storage device according to an example embodiment is applied.

Referring to FIG. 19, an SSD system 20 may include a host 21 and a storage device 200.

The storage device 200 may correspond to the storage device 100 of FIG. 1 or the storage device 100 of FIG. 11. An operating method of the storage device 200 may correspond to the operating methods according to FIGS. 14, 16, 17, and 18.

The storage device 200 may exchange a signal SIG with the host 21 through a signal connector 251 and may receive a power PWR through a power connector 252.

The storage device 200 may include an SSD controller 210, a plurality of non-volatile memories 221 to 22N, an auxiliary power supply 230, and a buffer memory 240.

The SSD controller 210 may control the non-volatile memories 221 to 22N in response to the signal SIG from the host 21. The plurality of non-volatile memories 221 to 22N may operate under control of the SSD controller 210.

In an example embodiment, the SSD controller 210 may perform the DMA read operation with the plurality of non-volatile memories 221 to 22N and may update a page count value of a DMA register. When data read from the plurality of non-volatile memories 221 to 22N through the DMA read operation include an uncorrectable error, the SSD controller 210 may determine an optimized read voltage based on the page count value of the DMA register. The SSD controller 210 may perform the read retry based on the optimized read voltage.

The auxiliary power supply 230 may be connected with the host 21 through the power connector 252. The auxiliary power supply 230 may be charged by the power PWR from the host 21. When the power is not smoothly supplied from the host 21, the auxiliary power supply 230 may provide a power for driving the SSD system 20.

The buffer memory 240 may be used as a buffer memory of the storage device 200.

By way of summation and review, immediately after data are stored in a non-volatile memory device, i.e., at an initial time, a voltage distribution of memory cells of the non-volatile memory device may be similar to a program voltage distribution. After a considerable time passes from a time when the data are stored in the non-volatile memory device, i.e., at a retention time, the voltage distribution of the memory cells of the non-volatile memory device may be lower than the program voltage distribution. However, the lower voltage distribution of memory cells may cause the reduction of reliability of the non-volatile memory device. Accordingly, a read retry technique for adjusting a read voltage at the retention time may be employed.

In general, an additional input/output (I/O) operation may be used to obtain a logical count of “1” or “0” indicating a characteristic of a memory cell, and an additional operation that allows a memory controller to sense a logical count change may be used. Also, a plurality of sensing operations may be used to obtain distribution information, in which case a logical complexity such as an XOR operation may be increased. Also, an additional sensing and logical operation may be used to obtain count information between two read voltages. Thus, an additional read operation may be used to obtain characteristic information of a memory cell (e.g., a threshold voltage distribution), but this may cause a decrease of a speed of a memory device.

As described above, embodiments relate to a read retry, and more particularly, relate to an operating method of a storage controller performing a read retry by using a count value of a direct memory access, a storage device including the storage controller, and an operating method of the storage device. Embodiments may provide an operating method of a storage controller performing read retry by using a count value of a direct memory access, a storage device including the storage controller, and an operating method of the storage device. Embodiments may provide an operating method of a storage controller performing read retry by using a count value of a direct memory access, a storage device including the storage controller, and an operating method of the storage device are provided. Embodiments may provide an operating method of a storage controller that has an improved data processing speed and improved reliability by optimizing a read voltage based on a count value of a direct memory access without an additional read operation after an uncorrectable error occurs, a storage device including the storage controller, and an operating method of the storage device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of operating a storage controller that communicates with a non-volatile memory device, the method comprising:
performing a first direct memory access (DMA) read operation on data stored in the non-volatile memory device, based on a first read voltage;
updating a page count value of a DMA register, based on the first DMA read operation;
determining whether data read by the first DMA read operation include an uncorrectable error;
when it is determined that the data read by the first DMA read operation include the uncorrectable error, determining a second read voltage different from the first read voltage, based on the updated page count value of the DMA register, without an additional read operation on the data stored in the non-volatile memory device; and
performing a second DMA read operation on the data stored in the non-volatile memory device, based on the second read voltage.

2. The method as claimed in claim 1, wherein the second read voltage is a read voltage optimized on a page corresponding to the first read voltage, based on a difference between the updated page count value of the DMA register and an idle count value indicating a number of memory cells having a first bit value within the page at an initial time.

3. The method as claimed in claim 1, wherein:
the non-volatile memory device includes a plurality of memory cells, each of which has a first bit value or a second bit value within a page corresponding to the first read voltage, and
the performing of the first DMA read operation on the data stored in the non-volatile memory device, based on a first read voltage, includes counting a number of memory cells having the first bit value from among the plurality of memory cells based on the first read voltage, and
the updating of the page count value of the DMA register, based on the first DMA read operation, includes updating the page count value of the DMA register based on the counted number of memory cells having the first bit value.

4. The method as claimed in claim 1, wherein the determining of the second read voltage includes:
referring to the updated page count value of the DMA register; and
determining, using a machine learning device of the storage controller, the second read voltage based on the updated page count value of the DMA register and a machine learning model.

5. The method as claimed in claim 4, wherein, before performing the first DMA read operation, the machine learning model includes a first parameter and a second parameter which are determined by a machine learning algorithm based on a training data set corresponding to the first read voltage.

6. The method as claimed in claim 5, wherein the determining of the second read voltage based on the updated page count value of the DMA register and the machine learning model by the machine learning device of the storage controller includes determining, by the machine learning device, a value obtained by adding the second parameter and a product of the first parameter and the updated page count value of the DMA register, as the second read voltage.

7. The method as claimed in claim 1, wherein:
the non-volatile memory device includes a plurality of memory cells, each of which has one of an erase state, a first programming state, a second programming state, a third programming state, a fourth programming state, a fifth programming state, a sixth programming state, and a seventh programming state, and
each of the erase state and the first to seventh programming states indicates a first bit value or a second bit value within a page corresponding to the first read voltage.

8. The method as claimed in claim 7, wherein:
the page corresponding to the first read voltage is a first logical page indicating a most significant bit of a triple level cell, and
the first read voltage is a voltage for distinguishing the sixth programming state of an initial time from the seventh programming state of the initial time.

9. The method as claimed in claim 7, wherein:
the page corresponding to the first read voltage is a second logical page indicating a center significant bit of a triple level cell, and
the first read voltage is a voltage for distinguishing the fifth programming state of an initial time from the sixth programming state of the initial time.

10. The method as claimed in claim 7, wherein:
the page corresponding to the first read voltage is a third logical page indicating a least significant bit of a triple level cell, and
the first read voltage is a voltage for distinguishing the fourth programming state of an initial time from the fifth programming state of the initial time.

11. The method as claimed in claim 1, wherein the determining of whether the data read by the first DMA read operation include the uncorrectable error includes:
performing error correction of the data read by the first DMA read operation;
determining whether the error-corrected data from the error correction include the uncorrectable error; and
when it is determined that the error-corrected data include no uncorrectable error, outputting the error-corrected data as user data to an external device.

12. A method of operating a storage device that includes a non-volatile memory device, which stores data, and a storage controller, which controls the non-volatile memory device, the method comprising:
performing a first direct memory access (DMA) read operation on the data stored in the non-volatile memory device, based on a first read voltage;
updating a page count value of a DMA register, based on the first DMA read operation;
determining whether the data read by the first DMA read operation include an uncorrectable error;
when it is determined that the data read by the first DMA read operation include the uncorrectable error, determining a second read voltage different from the first read voltage, based on the updated page count value of the DMA register, without an additional read operation on the data stored in the non-volatile memory device; and
performing a second DMA read operation on the data stored in the non-volatile memory device, based on the second read voltage.

13. The method as claimed in claim 12, wherein the second read voltage is a read voltage optimized on a page corresponding to the first read voltage, based on a difference between the updated page count value of the DMA register and an idle count value indicating a number of memory cells having a first bit value within the page at an initial time.

14. The method as claimed in claim 12, wherein:
the non-volatile memory device includes a plurality of memory cells, each of which has a first bit value or a second bit value within a page corresponding to the first read voltage, and
the performing of the first DMA read operation and the updating of the page count value of the DMA register includes:
counting a number of memory cells having the first bit value from among the plurality of memory cells based on the first read voltage; and
updating the page count value of the DMA register based on the counted number of memory cells having the first bit value.

15. The method as claimed in claim 12, wherein the determining of the second read voltage includes:
referring to the updated page count value of the DMA register; and
determining, by a machine learning device of the storage controller, the second read voltage based on the updated page count value of the DMA register and a machine learning model.

16. A storage device, comprising:
a non-volatile memory device including a plurality of memory cells for storing data; and
a storage controller, wherein the storage controller is configured to:
perform a first direct memory access (DMA) read operation on data stored in the non-volatile memory device, based on a first read voltage;
update a page count value of a DMA register;
determine whether the data read by the first DMA read operation include an uncorrectable error; and
when it is determined that the data read by the first DMA read operation include the uncorrectable error,
determine a second read voltage different from the first read voltage based on the updated page count value of the DMA register, and
perform a second DMA read operation on the data stored in the non-volatile memory device, based on the second read voltage.

17. The storage device as claimed in claim 16, wherein:
the storage controller includes:
a memory storing firmware;
a DMA controller configured to perform the first DMA read operation and the second DMA read operation of the non-volatile memory device, under control of the firmware;
a DMA register configured to store the page count value, which is updated by the DMA controller;
an error correction code (ECC) engine configured to determine whether the data read by the first DMA read operation include the uncorrectable error; and
a read voltage controller configured to control a read voltage of the non-volatile memory device to the first read voltage or the second read voltage, and
in response to the ECC engine determining that the data read by the first DMA read operation include the uncorrectable error, the firmware determines the second read voltage based on the updated page count value of the DMA register and requests the second DMA read operation to the read voltage controller and the DMA controller.

18. The storage device as claimed in claim 17, wherein:
the firmware includes a machine learning device configured to determine the second read voltage based on the updated page count value of the DMA register, the machine learning device including:
a model generator including a first parameter and a second parameter determined by a machine learning algorithm; and
a calculator configured to determine the second read voltage based on the updated page count value of the DMA register, the first parameter, and the second parameter.

19. The storage device as claimed in claim 16, wherein:
each of the plurality of memory cells has one of an erase state, a first programming state, a second programming state, a third programming state, a fourth programming state, a fifth programming state, a sixth programming state, and a seventh programming state, and
each of the erase state and the first to seventh programming states indicates a first bit value or a second bit value within a page corresponding to the first read voltage.

20. The storage device as claimed in claim 16, wherein the storage controller is further configured to, when it is determined that the data read by the first DMA read operation include the uncorrectable error, determine the second read voltage without an additional read operation for the data stored in the non-volatile memory device.
